(19) United States
(12) Patent Application Publication
(10) Pub. No.: US 2014/0192484 A1
(43) Pub. Date: Jul. 10, 2014

(54) FAN CONTROLLING SYSTEM AND ELECTRONIC DEVICE USING SAME

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: LEI LIU, Shenzhen (CN); WEI-DONG CONG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/141,481

(22) Filed: Dec. 27, 2013

(30) Foreign Application Priority Data
Jan. 4, 2013 (CN) 2013100008140

(51) Int. Cl. H05K 7/20

(52) U.S. Cl. CPC H05K 7/20136
USPC 361/695

(57) ABSTRACT

A fan controlling system of an electronic device connects a fan to an external power source when the electronic device operates. The fan controlling system switches the fan to connect to a backup power source of the electronic device when the electronic device is turned off.

### BACKGROUND

1. Technical Field

The present disclosure relates to controlling systems, and particularly to a fan controlling system.

2. Description of Related Art

Generally, an electronic device is cooled by a fan. However, the fan usually shares a same power source with the electronic device, so the fan is shut down when the electronic device is turned off. Thus, heat accumulated in the electronic device when the electronic device turns off cannot be dissipated by the fan.

Therefore, it is desirable to provide a means to overcome the above-mentioned problems.

### BRIEF DESCRIPTION OF THE DRAWINGS

Many aspects of the embodiments can be better understood with references to the following drawing. The components in the drawing are not necessarily drawn to scale, the emphasis instead being placed upon clearly illustrating the principles of the embodiments.

FIG. 1 is a diagram of a first embodiment of a fan controlling system.

FIG. 2 is a diagram of a second embodiment of a fan controlling system.

FIG. 3 is an isometric view of a fan of the fan controlling system of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The references “a plurality of” and “a number of” mean “at least two.”

Embodiments of the disclosure are described with reference to the drawing.

In general, the word “module”, as used herein, refers to logic embodied in hardware or firmware, or to a collection of software instructions, written in a programming language, such as, Java, C, or assembly. One or more software instructions in the modules may be embedded in firmware, such as in an EPROM. The modules described herein may be implemented as either software and/or hardware modules and may be stored in any type of non-transitory computer-readable medium or other storage unit. Some non-limiting examples of non-transitory computer-readable median include CDs, DVDs, BLU-RAY, flash memory, and hard disk drives.

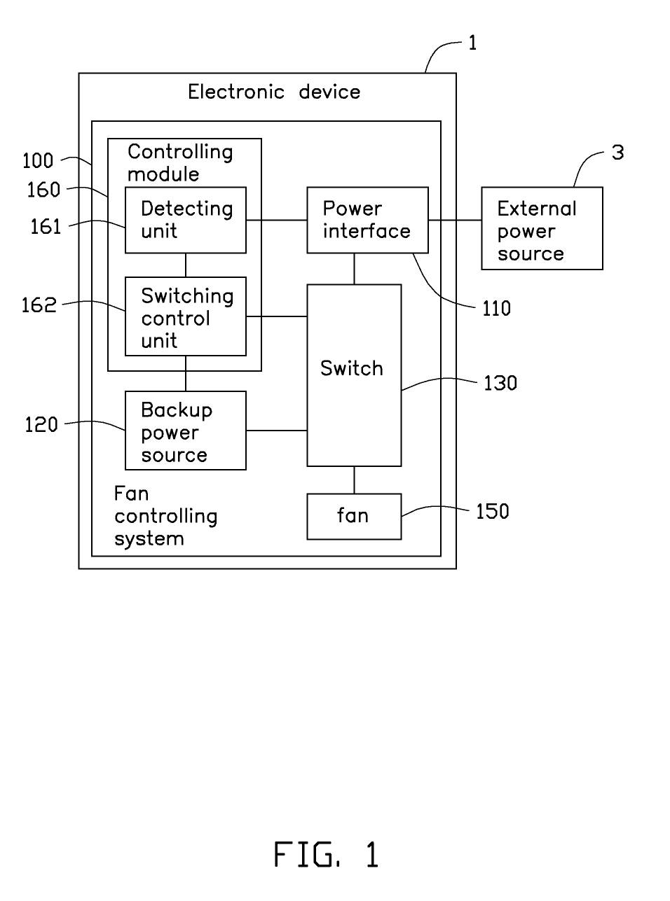

FIG. 1 shows a first embodiment of an electronic device 1 including a fan controlling system 100 for dissipating heat of the electronic device 1. The fan controlling system 100 includes a fan 150, a power interface 110, a switch 130, a backup power source 120, and a controlling module 160. The power interface 110 is electrically connected to an external power source 3 to provide power to the electronic device 1. The power interface 110, the backup power source 120, the fan 150, and the controlling module 160 are individually electrically connected to the switch 130. The controlling module 160 controls the switch 130 to connect the fan 150 to the external power source 3 via the power interface 110 when the electronic device 1 operates. The controlling module 160 controls the switch 130 to connect the backup power source 120 to the fan 150 when the electronic device 1 is turned off. Thus, the external power source 3 provides power to drive the fan 150 when the electronic device 1 operates, and the backup power source 120 provides power to drive the fan 150 for a predetermined time after the electronic device 1 is turned off.

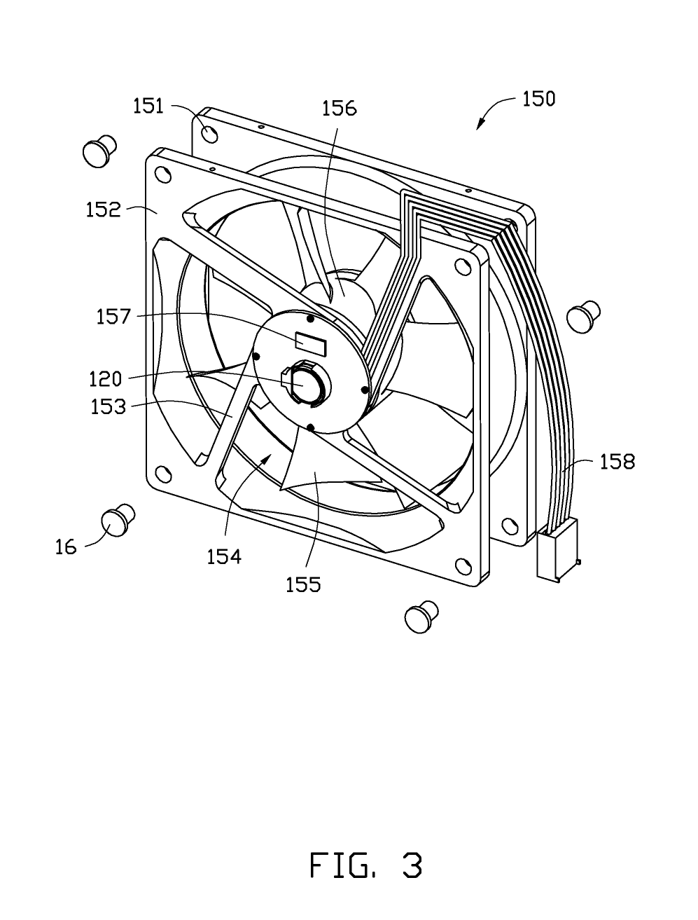

FIG. 3 show that the fan 150 includes a frame 152, a number of holding ribs 153, a motor 156, a number of blades 155 formed on the motor 156, a processor 157, and a connecting wire 158. The frame 152 defines a number of threaded through holes 151 and a receiving space 154 therein. The motor 156 and the blades 155 are received in the receiving space 154. The fan 150 is fastened to the electronic device 1 via a number of screws 16 received through the threaded through holes 151. The holding ribs 153 fix the motor 156 in the receiving space 154. The blades 155 radially extend from an outer surface of the motor 156. The connecting wire 158 connects the switch 130 to the motor 156. The processor 157 is located on the frame 152. The controlling module 160 is a firmware embedded in the processor 157. In the illustrated embodiment, the frame 152 is substantially rectangular, and there are four pairs of threaded through holes 151 defined in four corners of the frame 152, respectively.

In one embodiment, the backup power source 120 is a rechargeable battery. The backup power source 120 is electrically connected to the power interface 110 via the switch 130, and is fastened to the frame 152. The backup power source 120 is charged by the external power source 3 when the electronic device 1 operates.

The controlling module 160 includes a detecting unit 161 and a switching control unit 162 electrically connected to the detecting unit 161. The detecting unit 161 is electrically connected to the power interface 110.

The detecting unit 161 detects whether a connection between the electronic device 1 and the external power source 3 is cut off. The detecting unit 161 transmits a turn off instruction to the switching control unit 162 when the connection between the electronic device 1 and the external power source 3 is cut off. The detecting unit 161 transmits a turn on instruction to the switching control unit 162 when the electronic device 1 is connected to the external power source 3.

The switching control unit 162 controls the switch 130 to connect the fan 150 to the power interface 110 when the switching control unit 162 receives the turn on instruction from the detecting unit 161. The fan 150 is powered by the external power source 3 via the power interface 110 when the electronic device 1 operates.

The switching control unit 162 controls the switch 130 to connect the fan 150 to the backup power source 120 when the switching control unit 162 receives the turn off instruction. The fan 150 is powered by the backup power source 120 when the electronic device 1 is turned off. Thus, the fan 150 still operates after the electronic device 1 is turned off to dissipate the heat accumulated in the electronic device 1.

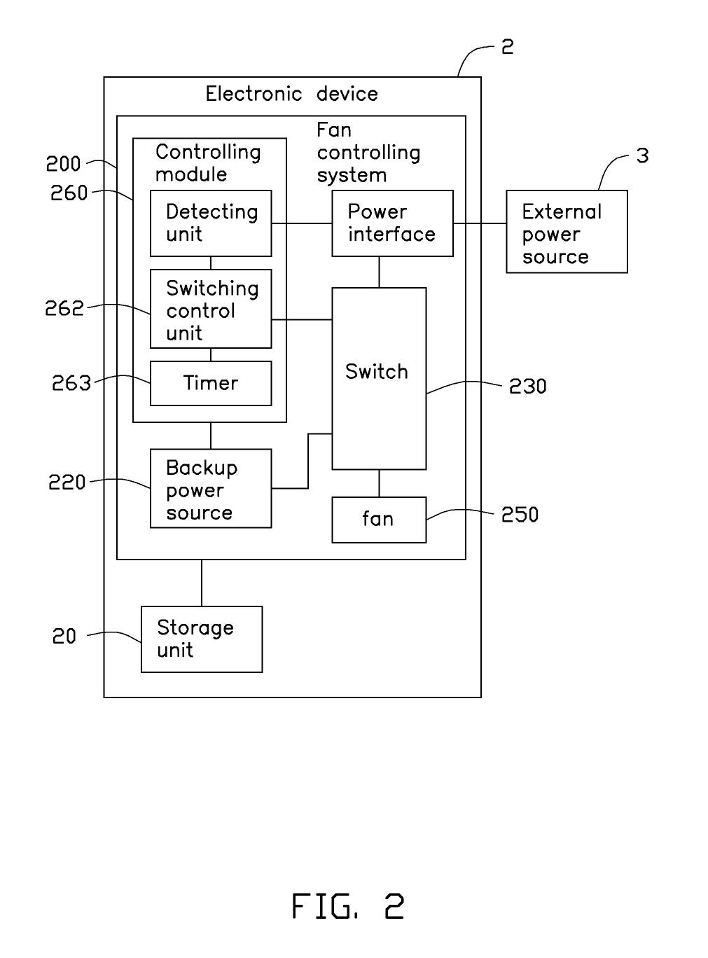

FIG. 2 shows a second embodiment of an electronic device 2 including a fan controlling system 200. A controlling module 260 of the fan controlling system 200 further includes a timer 263 connected to a switching control unit 262, and the electronic device 2 further includes a storage unit 20. The controlling module 260 is software instructions stored in the storage unit 20 and executed by the processor 157.

The timer 263 presets a time duration (hereinafter “dissipating time duration”) for a fan 250 to operate after the electronic device 2 is turned off. The switching control unit 262 transmits the turn off instruction to the timer 263 when the connection between the electronic device 2 and the external power source 3 is cut off. The timer 263 starts a timing process when the timer 263 receives the turn off instruction, and transmits a finish instruction to the switching control unit 262 within the dissipating time duration. The switching control unit 262 controls the switch 230 to disconnect the fan 250 from the backup power source 220 the switching control unit 262 receives the finish instruction. Thus, the fan 250 operates during the dissipating time duration after the electronic device 2 is turned off.

While various exemplary and preferred embodiments have been described, it is to be understood that the present disclosure is not limited thereto. On the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A fan controlling system of an electronic device, comprising:
a power interface connected to an external power source for providing power to the electronic device;
a switch connected to the power interface;
a backup power source connected to the switch;
a fan connected to the switch; and
a controlling module;
wherein the controlling module controls the switch to connect the fan with the external power source via the power interface when the electronic device operates and controls the switch to connect the fan with the backup power source when the electronic device turns off, and the backup power source provides power to the fan after the electronic device turns off.

2. The fan controlling system of claim 1, wherein the controlling module comprises a detecting unit connected to the power interface and a switching control unit connected to the detecting unit, the detecting unit transmits a turn off instruction to the switching control unit when the connection between the electronic device and the external power source is cut off, the detecting unit transmits a turn on instruction to the switching control unit when the electronic device is still connected to the external power source, the switching control unit controls the switch to connect the fan with the power interface when receives the turn on instruction from the detecting unit, and the switching control unit controls the switch to connects the fan with the backup power source when receives the turn off instruction.

3. The fan controlling system of claim 2, wherein the controlling module further comprises a timer connected to the switching control unit, the timer preset a dissipating time duration, the switching control unit transmits the turn off instruction to the timer when the connection between the electronic device and the external power source is cut off, the timer starts a timing process when receives the turn off instruction and transmits a finish instruction to the switching control unit within the dissipating time duration, and the switching control unit control the switch to disconnect the fan with the backup power source when receives the finish instruction.

4. The fan controlling system of claim 1, wherein the fan comprises a frame, a plurality of holding ribs, a motor, a plurality of blades radially extending from an outer surface of the motor, a processor, and a connecting wire connected to the switch, the frame defines receiving space to receive the motor and the blades, the holding ribs fix the motor in the receiving space, and the processor is fastened to the frame.

5. The fan controlling system of claim 4, wherein the frame defines a plurality of threaded through holes therein, and the fan is fastened to the electronic device via a plurality of screws passing through the threaded through holes.

6. The fan controlling system of claim 4, wherein the controlling module is a firmware embedded in the processor.

7. An electronic device, comprising:
a storage device; and
a fan controlling system received in the electronic device to dissipate heat, comprising:
a power interface connected to an external power source for providing power to the electronic device;
a switch connected to the power interface;
a backup power source connected to the switch;
a fan connected to the switch and comprising a processor; and
a controlling module stored in the storage device and executed by the processor;
wherein the controlling module controls the switch to connect the fan with the external power source via the power interface when the electronic device operates and controls the switch to connect the fan with the backup power source when the electronic device turns off, and the backup power source provides power to the fan after the electronic device turns off.

8. The electronic device of claim 7, wherein the controlling module comprises a detecting unit connected to the power interface and a switching control unit connected to the detecting unit, the detecting unit transmits a turn off instruction to the switching control unit when the connection between the electronic device and the external power source is cut off, the detecting unit transmits a turn on instruction to the switching control unit when the electronic device is still connected to the external power source, the switching control unit controls the switch to connect the fan with the power interface when receives the turn on instruction from the detecting unit, and the switching control unit controls the switch to connects the fan with the backup power source when receives the turn off instruction.

9. The electronic device of claim 8, wherein the controlling module further comprises a timer connected to the switching control unit, the timer preset a dissipating time duration, the switching control unit transmits the turn off instruction to the timer when the connection between the electronic device and the external power source is cut off, the timer starts a timing process when receives the turn off instruction and transmits a finish instruction to the switching control unit within the dissipating time duration, and the switching control unit control the switch to disconnect the fan with the backup power source when receives the finish instruction.

10. The electronic device of claim 1, wherein the fan comprises a frame, a plurality of holding ribs, a motor, a plurality of blades radially extending from an outer surface of the motor, a processor, and a connecting wire connected to the switch, the frame defines receiving space to receive the motor and the blades, the holding ribs fix the motor in the receiving space, and the processor is fastened to the frame.

11. The electronic device of claim 10, wherein the frame defines a plurality of threaded through holes therein, and the fan is fastened to the electronic device via a plurality of screws passing through the threaded through holes.
